(19) United States
(12) Patent Application Publication
(10) Pub. No.: US 2026/0038763 A1
(43) Pub. Date: Feb. 5, 2026

(54) ION STRIPPING APPARATUS WITH INTEGRATED QUADRUPOLES

(71) Applicant: Axcelis Technologies, Inc., Beverly, MA (US)

(72) Inventors: Wilhelm Platow, Newburyport, MA (US); Robert D. DuBois, Bend, OR (US); Bo Vanderberg, Gloucester, MA (US)

(21) Appl. No.: 19/286,750

(22) Filed: Jul. 31, 2025

Related U.S. Application Data
(60) Provisional application No. 63/678,095, filed on Aug. 1, 2024.

(51) Int. Cl. H01J 37/02; H01J 37/21; H01J 37/317

(52) U.S. Cl. CPC H01J 37/026; H01J 37/21; H01J 37/3171; H01J 2237/0473; H01J 2237/04922; H01J 2237/04924

(57) ABSTRACT

An ion implantation system has a first linear accelerator for accelerating ions of an ion beam to a first energy along a beam path. A second linear accelerator positioned downstream of the first linear accelerator along the beam path accelerates the ions to a second energy. A charge stripper has a stripper tube with a passageway positioned between the first and second linear accelerators. A charge stripping medium is provided in the passageway to strip at least one electron from the ions as the ion beam passes through the charge stripping medium. A focusing apparatus is associated with the stripper tube to control a trajectory of the ions within the passageway of the stripper tube. The focusing apparatus can be two or more quadrupoles and include an electrostatic lens, a magnet, a solenoid, or a Einzel lens.

### REFERENCE TO RELATED APPLICATIONS

This application claims the benefit of U.S. Provisional Application Ser. No. 63/678,095 filed Aug. 1, 2024, entitled, “ION STRIPPING APPARATUS WITH INTEGRATED QUADRUPOLES”, the contents of all of which are herein incorporated by reference in their entirety.

### TECHNICAL FIELD

The present disclosure generally relates to a charge stripping system for altering a charge state of ions of an ion beam. The charge stripping system further controls a scattering of the ions as the ion beam passes through a charge stripper, thereby controlling a trajectory of the ions as the ion beam emerges from the charge stripper.

### BACKGROUND

In the manufacture of semiconductor devices, ion implantation is used to dope semiconductors with impurities. Ion implantation systems (also called ion implanters) are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

### SUMMARY

The following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

Aspects of the disclosure facilitate ion implantation processes for implanting ions into a workpiece. According to one exemplary aspect, an ion implantation system is provided having an ion source configured to form an ion beam, a beamline assembly configured to selectively transport the ion beam, and an end station is configured to accept the ion beam for implantation of the desired ions into a workpiece. In accordance with one exemplary aspect, the ion implantation system comprises a first linear accelerator configured to accelerate ions of an ion beam to a first energy along a beam path. A second linear accelerator is positioned downstream of the first linear accelerator along the beam path, wherein the second linear accelerator is configured to accelerate the ions of the ion beam to a second energy. The first and second accelerators, for example, can comprise respective RF linear accelerators.

In accordance with one example, the present disclosure provides a charge stripping system for altering a charge state of the ions of the ion beam passing through a charge stripper in an ion implantation system. The charge stripping system of the present disclosure further controls a scattering of the ions as the ion beam passes through the charge stripper, thereby controlling a trajectory of the ions as the ion beam emerges from the charge stripper. According to one example, the charge stripper is positioned within a charge stripper housing between the first accelerator and the second accelerator of the ion implantation system along the beam path of the ion beam.

In one example aspect, the charge stripper comprises a stripper tube and a focusing apparatus configured to mitigate the scattering of ion trajectories by refocusing the ions as they pass through the stripper tube. In one example embodiment, the focusing apparatus comprises a plurality of quadrupoles generally surrounding the stripper tube, whereby the plurality of quadrupoles are configured to mitigate the scattering of ion trajectories of the ion beam. The plurality of quadrupoles, for example, can comprise at least two electrostatic quadrupoles or at least two magnetic quadrupoles. In an alternative example, the focusing apparatus comprises one or more of a solenoid or an Einzel lens associated with the stripper tube and configured to mitigate a scattering of ion trajectories of the ion beam.

The charge stripping system, for example, can further comprise a gas source configured to selectively provide a stripper gas to the charge stripper, wherein the stripper gas is configured to strip one or more electrons from the ions of the ion beam as the ions pass through the stripper gas. For example, the gas source is selectively fluidly coupled to the stripper tube for selectively providing the stripper gas to a passageway within the stripper tube. Further, the charge stripping system can comprise a flow control apparatus configured to selectively control a flow of the stripper gas to the stripper tube of the charge stripper. A power supply, for example, can be further operably coupled to the focusing apparatus and configured to control the trajectory of the ions within the passageway of the stripper tube via one of a current and voltage supplied to the focusing apparatus.

In accordance with another example aspect of the disclosure, an ion implantation system is provided, wherein a first linear accelerator is configured to accelerate ions of an ion beam to a first energy along a beam path, and a second linear accelerator is positioned downstream of the first linear accelerator along the beam path and configured to accelerate the ions of the ion beam to a second energy. A charge stripper, for example, is positioned between the first linear accelerator and the second linear accelerator along the beam path, wherein the charge stripper comprises a stripper tube having a passageway configured to pass the ion beam therethrough. In one example, a gas source is configured to supply a stripper gas to the stripper tube, wherein the stripper gas is configured to strip at least one electron from the ions as the ion beam passes through the stripper gas. Alternatively, a stripper medium is positioned within the stripper to strip at least one electron from the ions as the ion beam passes through the stripper medium. A focusing apparatus is further associated with the stripper tube, wherein the focusing apparatus is configured to control a trajectory of the ions within the passageway of the stripper tube.

In yet another example aspect, a charge stripping system for an ion implantation system is provided, wherein the charge stripping system comprises a charge stripper positioned between a first RF linear accelerator and a second RF linear accelerator along a beam path of ions of an ion beam. The charge stripper, for example, comprises a stripper tube having a passageway therethrough and a focusing apparatus surrounding the stripper tube. A gas source can be configured to supply stripper gas to the passageway of the stripper tube, and a power is supply operably coupled to the focusing apparatus. Further, a controller is configured to control a trajectory of the ions within the passageway by controlling a current or a voltage from the power supply to the focusing apparatus.

In another aspect, a beam control apparatus is provided for focusing an ion beam passing through a charge stripper. The beam control apparatus, for example, comprises a stripper tube comprising a passageway configured to pass an ion beam through a charge stripping medium, wherein the ion beam comprises ions having an initial trajectory. Further, the beam control apparatus comprises a focusing apparatus configured to control a trajectory of the ions within the passageway of the stripper tube.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a schematic block diagram of an ion implantation system having a focusing apparatus for a stripper apparatus in accordance with several example aspects of the present disclosure.

FIG. 2 is a schematic block diagram of another ion implantation system having a focusing apparatus for a stripper apparatus in accordance with several example aspects of the present disclosure.

FIG. 3 illustrates a perspective view of an exemplary charge stripper in accordance with another aspect of the present disclosure.

FIG. 4 illustrates a cross-sectional view of the charge stripper of FIG. 3 in accordance with another aspect of the present disclosure.

FIG. 5 is a chart illustrating a scattering of ions for an example arsenic ion beam.

FIG. 6A is a perspective view of an electrostatic focusing apparatus for a stripper apparatus in accordance with several example aspects of the present disclosure.

FIG. 6B is a cross-sectional view of the electrostatic focusing apparatus for the stripper apparatus of FIG. 6A.

FIG. 6C is another cross-sectional view of the electrostatic focusing apparatus for the stripper apparatus of FIG. 6A.

FIG. 7A is a perspective view of a magnetic focusing apparatus for a stripper apparatus in accordance with several example aspects of the present disclosure.

FIG. 7B is a cross-sectional view of the magnetic focusing apparatus for the stripper apparatus of FIG. 7A.

FIG. 7C is another cross-sectional view of the magnetic focusing apparatus for the stripper apparatus of FIG. 7A.

### DETAILED DESCRIPTION

The present disclosure is directed generally toward an ion implantation system, and more particularly, toward a charge stripper system for stripping electrons from ions of an ion beam within the ion implantation system. The charge stripper system, for example, strips electrons from ions passing through a stripper tube of a charge stripper within said ion implantation system, whereby a focusing apparatus associated with the stripper tube controls the trajectory of the ions passing therethough.

Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

Ion implantation systems (also called ion implanters) can utilize ions having high charge states to achieve high energy implantations into a workpiece. While an ion beam having ions at high charge states can be extracted directly from an ion source, such an extraction of high charge state ions can substantially lower a beam current of the ion beam, typically by a factor of five to ten, each time the charge state is increased by one. The present disclosure contemplates an advantageous technique whereby low-charge state ions are extracted from the ion source and pre-accelerated to a medium energy. The low-charge state ions at the medium energy can then be guided through a so-called charge stripper, whereby electrons are stripped from the low-charge state ions to define higher-charge state ions. Higher-charge state ions at the medium energy can be accordingly-accelerated to a higher final energy. In this manner, higher beam currents of the ion beam can be achieved, as the charge stripping efficiency increases with higher energies. Additionally, the charge stripping efficiency can vary for different species of ions, such as boron, phosphorous, and arsenic, as well as varying based on the energy, pressure and considerations such as the kind of stripper gas utilized in the charge stripper and a configuration or length of the charge stripper. For example, after reaching equilibrium (e.g., based on an extended length of the charge stripper and an elevated pressure), a final charge distribution is generally independent of the initial charge state of the ions.

The present disclosure generally provides a charge stripping system for altering a charge state of ions of an ion beam passing through a charge stripper in an ion implantation system, while advantageously controlling a scattering of the ions as the ion beam passes through the charge stripper, thereby controlling a trajectory of the ions as the ion beam emerges from the charge stripper. The charge stripper can comprise a stripper tube and a focusing apparatus configured to mitigate the scattering of ion trajectories by refocusing the ions as they pass through the stripper tube. In one example embodiment, the focusing apparatus comprises a plurality of quadrupoles generally surrounding the stripper tube, whereby the plurality of quadrupoles are configured to mitigate the scattering of ion trajectories of the ion beam. In an alternative example, the focusing apparatus comprises one or more of a solenoid or one or more Einzel lenses associated with the stripper tube configured to mitigate the scattering of ion trajectories of the ion beam.

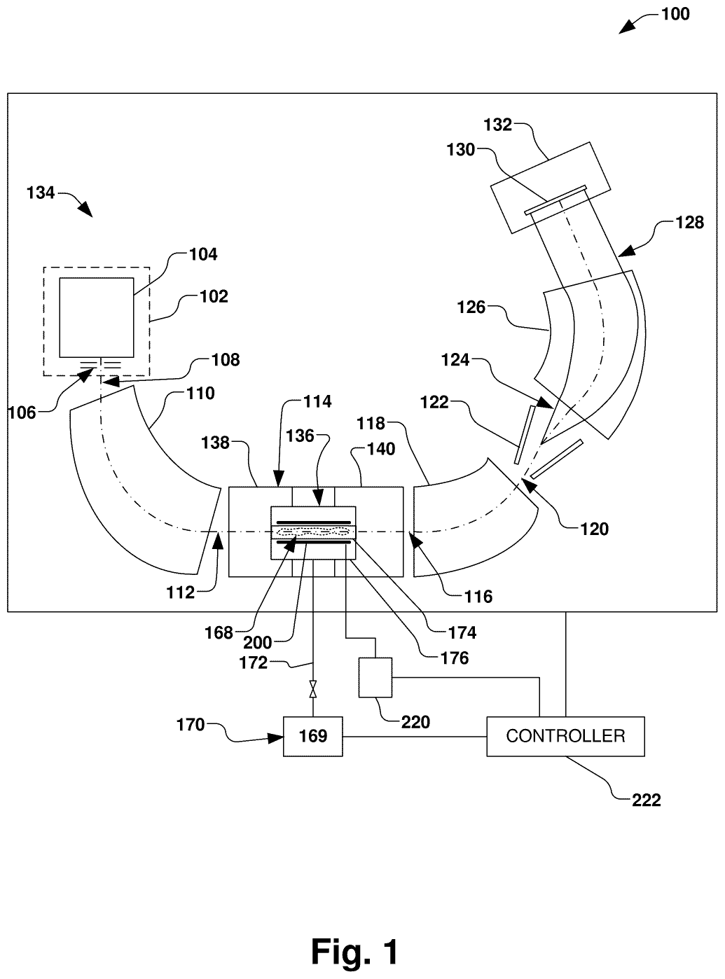

Referring now to the figures, in order to gain a better understanding of the present disclosure, FIG. 1 illustrates an ion implantation system 100 in accordance with various exemplified aspects of the present disclosure. The ion implantation system 100, for example, can sometimes be referred to as a post acceleration implanter, as will be discussed infra. The ion implantation system 100 of FIG. 1, for example, comprises an ion source 102, which comprises an ion source chamber 104 and an extraction electrode 106 to extract and accelerate ions to an intermediate energy, generally forming an ion beam 108. The ion beam 108 extracted from the ion source chamber 104, for example, can comprise any beam species, such as arsenic, boron, phosphorus, or other species.

A mass analyzer 110, for example, removes unwanted ion mass and charge species from the ion beam 108 to define a mass analyzed ion beam 112, whereby an accelerator 114 is configured to accelerate the analyzed ion beam to define an accelerated ion beam 116. In accordance with one example of the present disclosure, the accelerator 114, for example, comprises an RF linear particle accelerator (LINAC) in which ions are accelerated repeatedly by an RF field.

The ion implantation system 100, for example, further comprises an energy filter 118 positioned downstream of the accelerator 114, whereby the energy filter is configured to remove unwanted energy spectrum from the accelerated ion beam 116 emerging from the output of accelerator 114, thereby defining a final energy ion beam 120. A beam scanner 122, for example, is configured to scan the final energy ion beam 120 exiting from the energy filter 118, whereby the final energy ion beam is scanned back and forth at a fast frequency to define a scanned ion beam 124. The beam scanner 122, for example, is configured to electrostatically or electromagnetically scan the final energy ion beam 120 to define the scanned ion beam 124.

The scanned ion beam 124 is further passed into an angle corrector lens 126, wherein the angle corrector lens is configured to convert the fanning-out scanned beam 124 to a final ion beam 128. The angle corrector lens 126, for example, can be configured to parallelize and shift the scanned ion beam 124 to define the final ion beam 128. The angle corrector lens 126, for example, can comprise electromagnetic or electrostatic devices configured to define the final ion beam 128.

The final ion beam 128, for example, is subsequently implanted into a workpiece 130 (e.g., a semiconductor wafer) that can be selectively positioned in a process chamber or end station 132. The workpiece 130, for example, can be moved orthogonal to the final ion beam 128 (e.g., moving in and out of the paper) in a hybrid scan scheme to irradiate the entire surface of the workpiece 130 uniformly. It is noted that the present disclosure appreciates various other mechanisms and methods for scanning the final ion beam 128 with respect to the workpiece 130, and all such mechanisms and methods are contemplated as falling within the scope of the present disclosure.

The ion implantation system 100, for example, can be configured as a hybrid parallel-scan single-workpiece ion implantation system. The ion implantation system 100 for example, can also referred to as a post-acceleration implanter 134, since the accelerator 114 is positioned downstream of the mass analyzer 110 and upstream of the energy filter 118. Ion implanters of this type, for example, provide the energy filter 118 after the accelerator 114 in order to remove unwanted energy spectrum in the output of accelerator. It should be noted, however, that the present disclosure appreciates that various aspects of the present disclosure may be implemented in association with any type of ion implantation system, including, but not limited to the exemplary ion implantation system 100 of FIG. 1.

In one example, the final kinetic energy of ion particles passing through the accelerator 114 can be increased by increasing the charge state of the ions. While ion beams having higher charge states can be extracted directly from the ion source 102, such higher state ion beams typically have significantly lower beam currents (e.g., by a factor of 5-10 when increasing the charge state by one). The present disclosure appreciates that it can be more advantageous to achieve higher beam currents by pre-accelerating the mass analyzed ion beam 112 having lower charge state ions extracted from the ion source 102, and subsequently guiding them through a target gas where electrons are stripped from the ions, thus increasing the charge state of the ions. Then, the ions of the higher charge state can be post-accelerated to a final energy. Typically, higher beam currents can be achieved in this manner as the stripping efficiency increases with an increase in the energy of the ions. The stripping efficiency, for example, can vary based on ion species such as boron (B), phosphorus (P), and arsenic (As), as well varying based on the desired charge state and selection of the target gas.

Thus, in accordance with the present disclosure, a charge stripper 136 is provided to increase the charge state of the mass analyzed ion beam 112 that enters the accelerator 114. The charge stripper 136 is particularly advantageous for achieving high energy ion beams, as the energy increase (ΔE) of the ions is provided by:

$$Δ E = q V , \qquad ( 1 )$$

where V is the acceleration voltage and q is the charge state of the ions. Thus, in accordance with the present disclosure, the accelerator 114 comprises an RF linear accelerator having a number of accelerator stages (e.g., six or more) and resonators for generating an accelerating field, whereby the ion charge state can be increased in one embodiment by providing the charge stripper 136 within the accelerator 114 as shown in FIG. 1. As such, the ion particles are accelerated to a first energy before entering the charge stripper 136 via a first plurality of acceleration stages 138 within the accelerator 114. The ion particles are further accelerated to a second energy after exiting the charge stripper 136, for example, via a second plurality of acceleration stages 140 within the accelerator 114. For example, at least one of the plurality of accelerator stages can comprise the charge stripper 136 replacing the resonator(s) at that accelerator stage.

The first and second plurality of acceleration stages 138, 140 of the accelerator 114 can be either internal or external to the accelerator, and all such configurations are contemplated as falling within the scope of the present disclosure. For example, the accelerator 114 can take many forms and can comprise any number of accelerator stages defined by or within a single accelerator apparatus, such as illustrated in the example shown in FIG. 1. In another example, while not shown, the first plurality of acceleration stages of the accelerator 114 can be associated with the mass analyzer 110, whereby the ion beam 108 is both accelerated and mass analyzed before entering the charge stripper 136. In another example, the accelerator 114 can comprise a DC accelerator column (not shown). However, in such a configuration, components upstream of the DC accelerator column would be at high voltage potential.

It is noted that the energy filter 118 shown in the example of FIG. 1 can filter out some unwanted charge states. However, since the energy filter 118 is not immediately after the charge stripper 136 in the present example, the second plurality of acceleration stages 140 will accelerate the entire charge state distribution, thus potentially impeding a selection of the desired charge state, as the accelerated ion beam 116 may be contaminated with a charge state that has a different energy, but the same magnetic rigidity, as the desired charge state.

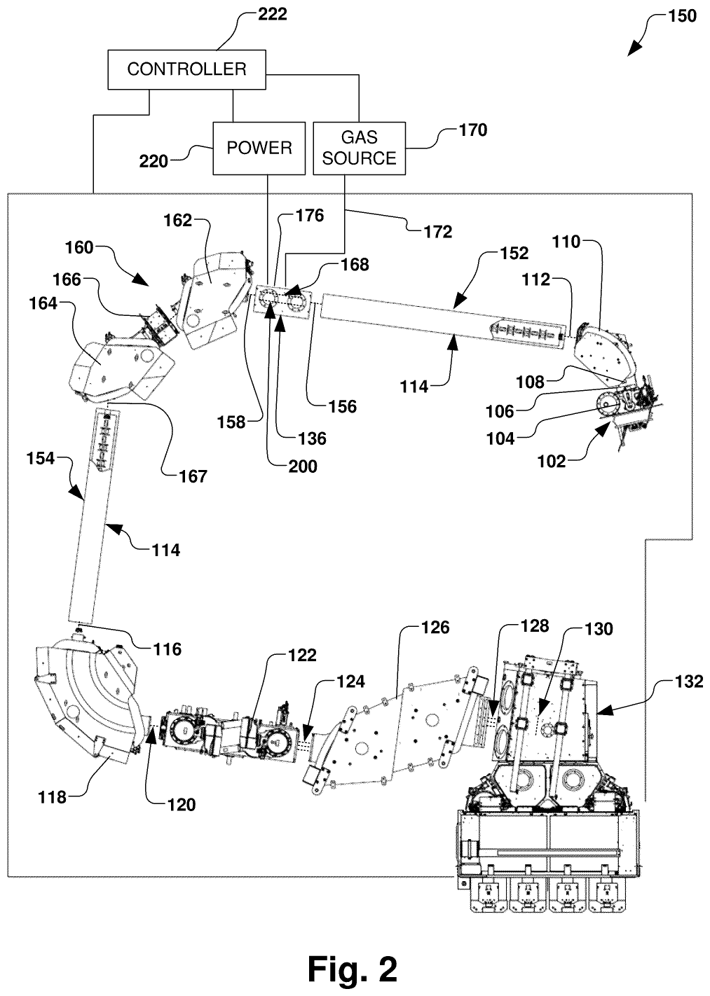

In another example, FIG. 2 illustrates an ion implantation system 150 having the accelerator 114 is generally defined by a pre-accelerator 152 and a post-accelerator 154, whereby the charge stripper 136 is positioned between the pre-accelerator section and post-accelerator section. The pre-accelerator 152, for example, is an RF linear accelerator configured to pre-accelerate ions of the mass analyzed ion beam 112 that have been extracted from the ion source 102 at a lower charge state, thus defining a pre-accelerated ion beam 156.

The charge stripper 136 thus increases the charge state of the pre-accelerated ion beam 156 as discussed above to define a higher charge state ion beam 158. A charge selector 160, for example, is further positioned downstream of the pre-accelerator 152 and charge stripper 136, whereby the charge selector is configured to select desired ions of the higher charge state after the stripping process performed in the pre-accelerator 152. The charge selector 160, for example, comprises first and second dipole magnets 162, 164 having a quadrupole magnet 166 disposed therebetween, whereby the charge selector selectively passes only selected ions of the higher charge state ion beam 158 to define a selected charge state ion beam 167. The selected charge state ion beam 167 thus enters the post-accelerator 154 in order to attain a maximum energy that is higher than the original-charge state ions and to define the accelerated ion beam 116.

In comparing the configurations of the ion implantation systems 100, 150 of respective FIGS. 1 and 2, the charge selector 160 shown in FIG. 2, for example, can be configured to select only a specific ion charge state of the desired ion species, while preventing other charge state ions from entering the post-accelerator 154. Thus, in some circumstances, the configuration of the ion implantation system 150 shown in FIG. 2 can provide a significantly purer energy spectrum of the desired ions after acceleration and charge selection by the provision of the pre-accelerator 152, post-accelerator 154, charge stripper 136, and charge selector 160, as compared to the configuration of the ion implantation system 100 illustrated in FIG. 1. Further, the ion implantation system 150 substantially avoids possible charge and energy contamination, as the probability of attaining beams having similar magnetic rigidity, but with different charge states and energies, is reduced to approximately zero.

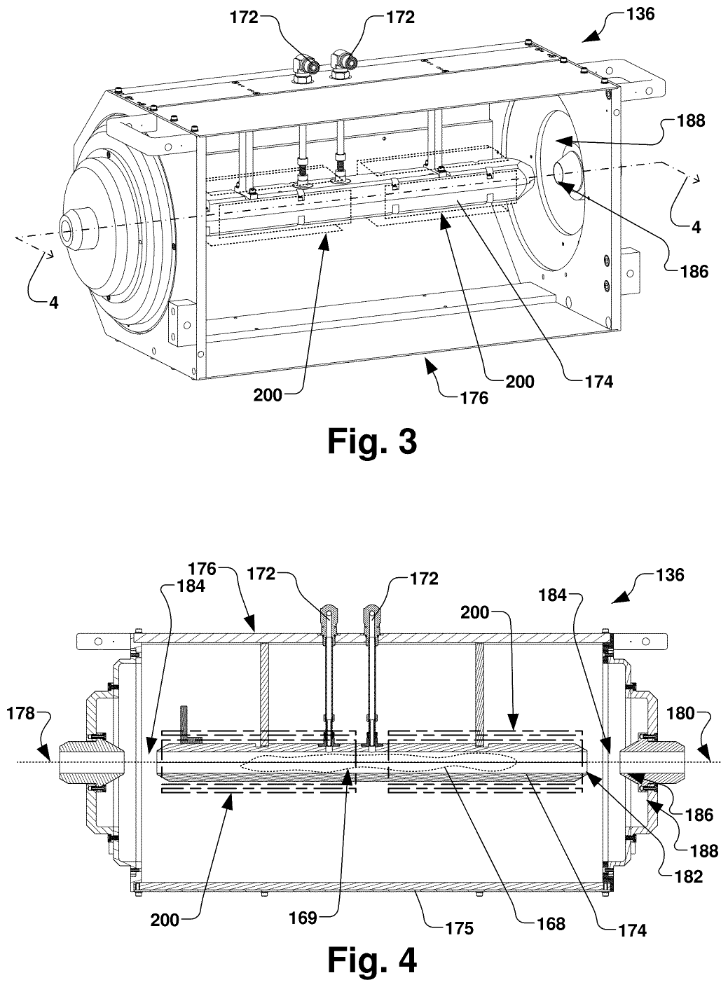

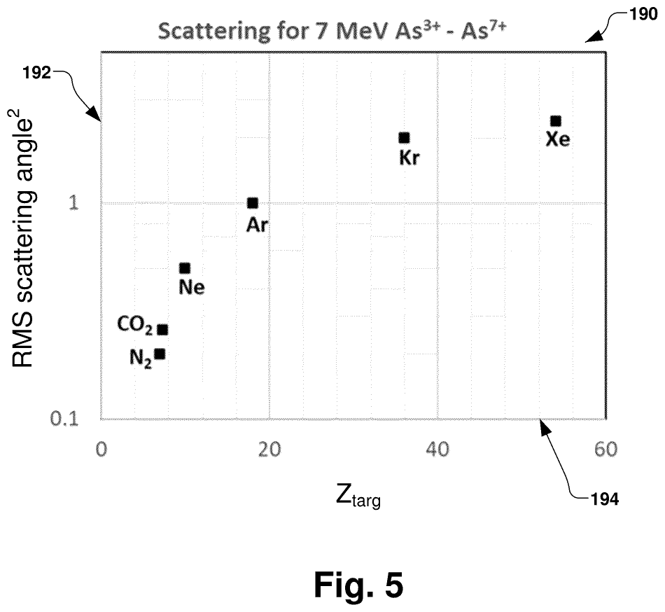

In accordance with various aspects of the disclosure, the charge stripper 136 of either of FIGS. 1 and 2, for example, comprises a stripper medium 168, such being filled with a stripper gas 169 supplied from a gas source 170 via one or more conduits 172, whereby the stripper gas is selected to strip electrons from the ions passing through the charge stripper. As an alternative to the stripper gas 169, the present disclosure also contemplates the stripper medium 168 comprising a stripper foil (not shown) or a stripper liquid (not shown) for stripping electrons from the ions passing through the charge stripper 136. FIGS. 3-4 illustrate a non-limiting example of the charge stripper 136, whereby the charge stripper comprises a stripper tube 174 positioned within a charge stripper housing 176 (e.g., an enclosure), whereby the stripper gas 169 of FIGS. 1-2 is selectively flowed into the stripper tube. It is to be noted that FIGS. 3-4 are not necessarily drawn to scale, and that variations in size, position, and configuration of the various features shown therein are contemplated as falling within the scope of the present disclosure.

As illustrated in cross-section of FIG. 4, the stripper gas 169 can be flowed through the one or more conduits 172 into the stripper tube 174 through which an inbound ion beam 178 passes. The inbound ion beam 178, for example, can comprise one of the mass analyzed ion beam 112 of FIG. 1 or the pre-accelerated ion beam 156 of FIG. 2, or any ion beam at any stage of acceleration of FIGS. 1-2. As the inbound ion beam 178 of FIG. 4, for example, passes through the stripper gas 169, electrons are stripped from the constituent ions, whereby an outbound ion beam 180 (e.g., the higher charge state ion beam 158 of FIG. 2) emerges at an exit 182 of the stripper tube 174. The outbound ion beam 180 of FIG. 4, for example, can have a charge state distribution associated therewith, whereby a desired charge state can be further selected by the charge selector 160 of FIG. 2 and define the selected charge state ion beam 167.

In accordance with one example, one or more gaps 184 upstream and downstream of the stripper tube 174 of FIG. 4 are differentially pumped to lower the pressure in the gaps and remove the stripper gas 169 therefrom, such that acceleration stages upstream and downstream of the charge stripper 136 are not negatively affected by the stripper gas. Such differential pumping can be provided in a plurality of stages, such as providing two or more gaps 184 upstream and downstream of the stripper tube 174. In one example, a pump (e.g., a turbo pump—not shown) can be provided to reduce or otherwise control a flow of the stripper gas 169 into adjacent sections associated with the accelerator 114 of FIGS. 1-2.

Further in accordance with the present disclosure, the charge stripper 136 is provided at ground potential. The charge stripper 136, for example, is thus particularly applicable to an RF linear accelerator-based ion implantation system, such as the so-called XEmax High Energy Implanter manufactured by Axcelis Technologies of Beverly, MA.

As illustrated in FIG. 4, ions of the inbound ion beam 178 entering the stripper tube 174 collide with the stripper gas 169 (e.g., atoms or molecules), and therefore change their charge state. Concurrently, the present disclosure appreciates that the angle of the ion trajectories of the ions of the inbound ion beam 178 can be affected due to scattering processes resulting in a deviation of the exiting ion trajectories of the outbound ion beam 180, whereby possible losses of ions at an exit aperture 186 or vacuum chamber walls 188 downstream of the stripper tube 174.

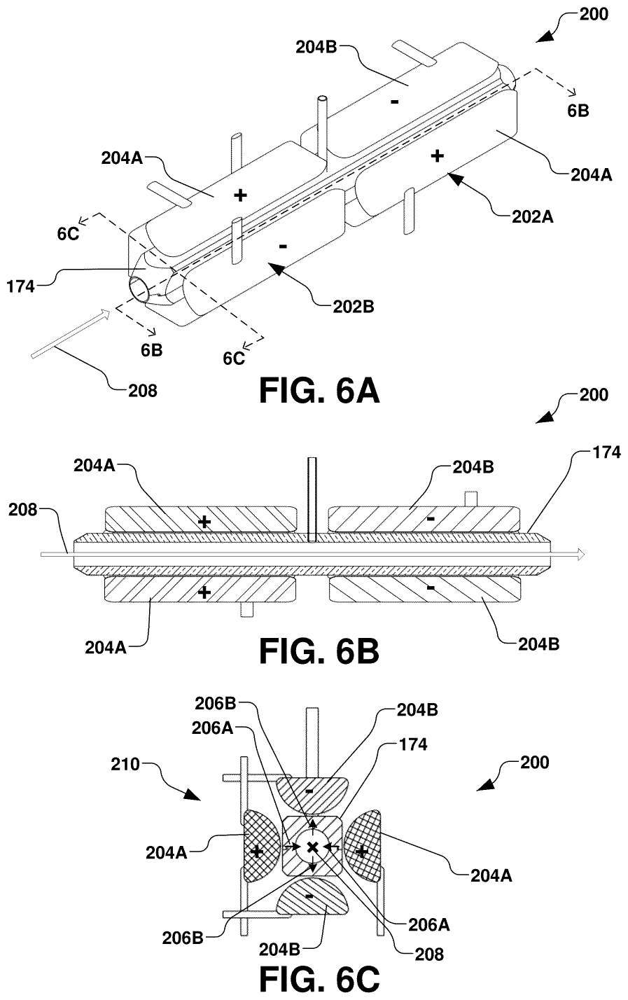

As shown in FIG. 5, a plot 190 illustrates an example of a 7 MeV As3+ ion beam that is stripped to define an As7+ ion beam, whereby a theoretical calculation shows a relationship between a scattering angle 192 (normalized to Argon) and an average Z value 194 of the stripper medium 168 of FIG. 1, whereby the average Z value is defined by the average atomic number of the atom or molecule of the stripper medium. The scattering angle 192, for example, is also proportional to the square root of the pressure of the stripper gas 169 of FIG. 4. It can be thus understood that an increase in the scattering angle 192, for example, can be undesirable due to its proportionality to the square root of the transmission, thus leading to a deleterious decrease of ion beam current or throughput.

The present disclosure contemplates mitigation of such a change of ion trajectories due to the above-described scattering processes in the stripper tube 174 by a provision of a focusing apparatus 200 illustrated schematically in FIGS. 1-4. The focusing apparatus 200 of FIGS. 1-4, for example, is provided within the charge stripper housing 176 and is configured to focus and control the trajectory of the ions within the stripper tube 174 as they progress from the inbound ion beam 178 to the outbound ion beam 180 of FIG. 4.

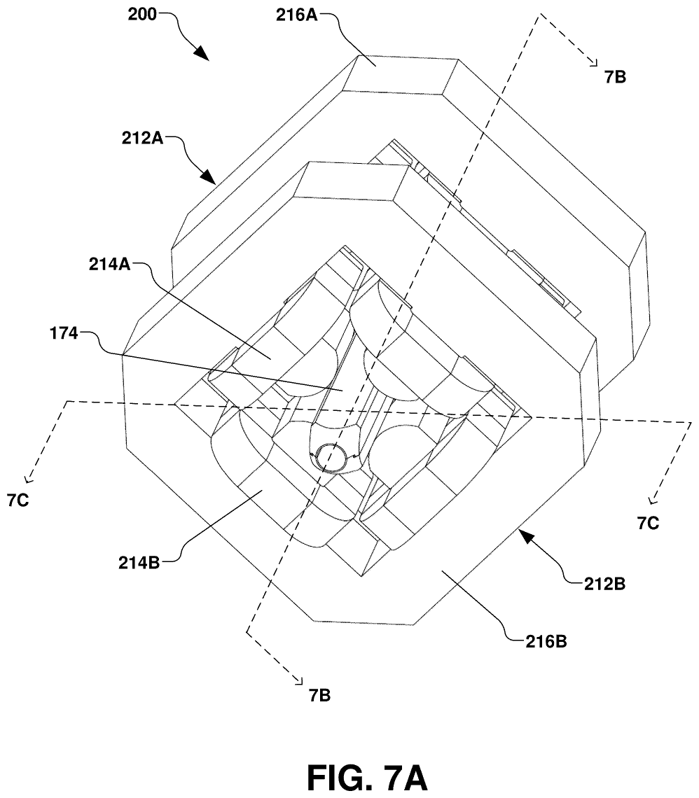

The focusing apparatus 200, for example, comprises two quadrupoles 202A, 202B surrounding the stripper tube 174, as illustrated in FIGS. 6A-6C. It shall be noted that while only two quadrupoles 202A, 202B are illustrated, any plurality of quadrupoles are contemplated as falling within the scope of the present disclosure. The two quadrupoles 202A, 202B illustrated in the example shown in FIGS. 6C, for example, comprise electrostatic quadrupoles 204A, 204B, whereby the quadrupole fields 206A, 206B focus an ion beam 208 passing through the stripper tube 174. In the case of the two quadrupoles 202A, 202B comprising the electrostatic quadrupoles 204A, 204B, the stripper tube 174 is comprised of an electrically non-conductive or insulative material, such as aluminum oxide, quartz, boron nitride, or the like.

The present disclosure appreciates that a single quadrupole 202A focuses the ion beam 208 passing through the stripper tube 174 in a first plane (e.g., illustrated by focusing arrows of quadrupole field 206A), while defocusing in a second plane (e.g., illustrated by defocusing arrows of quadrupole field 206B) that is perpendicular to the first plane. While defocusing of the ion beam 208 in the second plane is undesirable, providing the two quadrupoles 202A, 202B can advantageously achieve focusing in both the first and second planes, thus providing a stigmatic focusing system 210. It is again noted that while the present disclosure illustrates a quadrupole doublet, triplets and quadruplets of quadrupoles 202 are further considered.

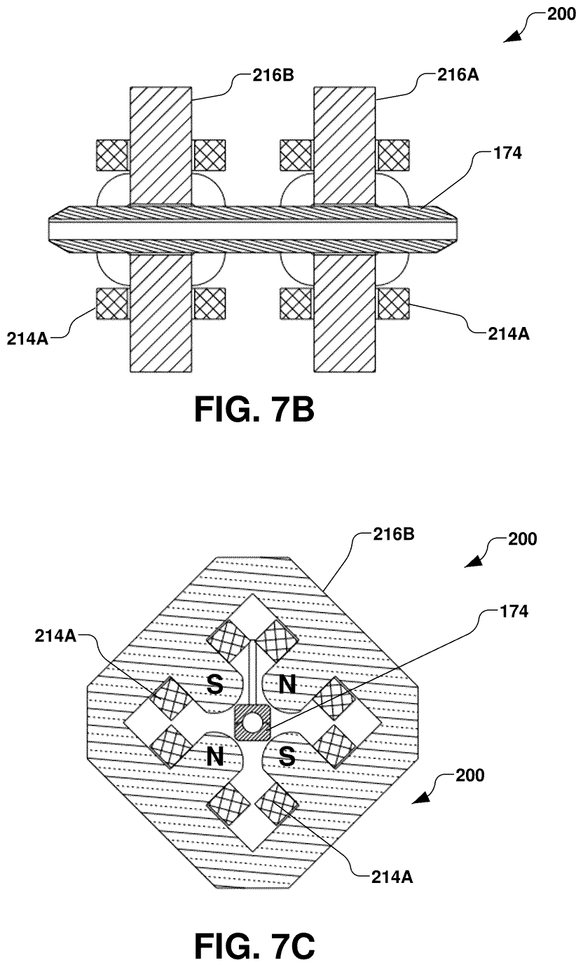

The present disclosure further contemplates the two quadrupoles 202 comprising two magnetic quadrupoles 212A, 212B, as illustrated in the example shown in FIGS. 7A-7C. As compared to the electrostatic quadrupoles 204A, 204B of FIGS. 6A-6C, the magnetic quadrupoles 212A, 212B are rotated 45 degrees to achieve the focusing of the ion beam 208 in the horizontal plane and vertical plane. The magnetic quadrupoles 212A, 212B, for example, can provide the stripper tube 174 as having or consisting of a conductive, but non-magnetic material, such as graphite, such as can be provided in the XEmax Ion Implantation System from Axcelis Technologies, Inc. of Beverly, MA. By providing the stripper tube 174 as comprising or consisting of a conductive material, various advantages can be achieved, such as minimizing charging effects that may be present in an insulative material, as well as limiting or avoiding a potential of metals contamination (e.g., from aluminum in aluminum oxide). Further, in some examples, the magnetic quadrupoles 212A, 212B can provide stronger fields without arcing, as compared to the electrostatic quadrupoles 204A, 204B of FIGS. 6A-6C, which can be a consideration for high energy ion implantation systems. The magnetic quadrupoles 212A, 212B of FIGS. 7A-7C, for example, comprise excitation coils 214A, 214B and return steel 216A, 216B surrounding the magnetic poles. Such excitation coils 214A, 214B and return steel 216A, 216B of the magnetic quadrupoles 212A, 212B can, however, be larger and heavier than the electrostatic quadrupoles 204A, 204B, thus increasing a footprint of the system due to an increase in length of the stripper tube 174. However, the length of the stripper tube 174 can have an advantage of needing less stripper gas 169 to provide the desired collisions of the ion beam with the stripper gas to yield the desired charge stripping.

In accordance with another example, a power supply 220 illustrated in FIGS. 1-2 can be provided, wherein the power supplies are configured to provide voltage to the electrostatic quadrupoles 204A, 204B of FIGS. 6A-6C or current to the magnetic quadrupoles 212A, 212B of FIGS. 7A-7C. Further, a controller 222 can be provided to control one or more of the power supply 220 and the gas source 170.

While linear accelerators are discussed above, the present disclosure further contemplates applicability of the focusing apparatus 200 and charge stripper 136 in a tandem accelerator.

Furthermore, the present disclosure contemplates a substitution of the two or more quadrupoles 202 with a solenoid (e.g., a solenoid having an axial magnetic field) or one or more Einzel lenses for lower energies and high charge states. Both of such lenses are typically weak at high energies; however, the present disclosure appreciates that one or more of a solenoid and an Einzel lens can further advantageously provide radial focusing. Arranging several of such lenses in series around the stripper tube 174 may provide adequate focusing strength after the pre-accelerator 152 of FIG. 1.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. A charge stripping apparatus comprising:
a charge stripper housing;
a stripper tube positioned within the charge stripper housing, wherein the stripper tube comprises a passageway configured to pass an ion beam therethrough, and wherein the ion beam comprises ions having an initial trajectory;
a charge stripping medium provided within the passageway and configured to strip at least one electron from the ions as the ion beam passes through the charge stripping medium; and
a focusing apparatus positioned within the charge stripper housing, wherein the focusing apparatus is configured to control a trajectory of the ions within the passageway of the stripper tube.

2. The charge stripping apparatus of claim 1, wherein the charge stripping medium comprises a stripper gas.

3. The charge stripping apparatus of claim 1, wherein the stripper tube consists of an electrically insulative material.

4. The charge stripping apparatus of claim 3, wherein the focusing apparatus comprises at least two electrostatic quadrupoles.

5. The charge stripping apparatus of claim 1, wherein the stripper tube comprises an electrically conductive material.

6. The charge stripping apparatus of claim 5, wherein the focusing apparatus comprises at least two magnetic quadrupoles.

7. The charge stripping apparatus of claim 1, further comprising a power supply operably coupled to the focusing apparatus and configured to control the trajectory of the ions within the passageway of the stripper tube via one of a current and voltage supplied to the focusing apparatus.

8. An ion implantation system comprising:
a first linear accelerator configured to accelerate ions of an ion beam to a first energy along a beam path;
a second linear accelerator positioned downstream of the first linear accelerator along the beam path and configured to accelerate the ions of the ion beam to a second energy;
a charge stripper positioned between the first linear accelerator and the second linear accelerator along the beam path, wherein the charge stripper comprises a charge stripper housing and a stripper tube, wherein the stripper tube is positioned within the charge stripper housing and comprises a passageway configured to pass the ion beam therethrough;
a gas source configured to supply a stripper gas to the stripper tube, wherein the stripper gas is configured to strip at least one electron from the ions as the ion beam passes through the stripper gas; and
a focusing apparatus associated with the stripper tube, wherein the focusing apparatus is configured to control a trajectory of the ions within the passageway of the stripper tube.

9. The ion implantation system of claim 8, wherein the stripper tube consists of an electrically insulative material.

10. The ion implantation system of claim 9, wherein the focusing apparatus comprises at least two electrostatic quadrupoles positioned within the charge stripper housing.

11. The ion implantation system of claim 8, wherein the stripper tube comprises an electrically conductive material.

12. The ion implantation system of claim 11, wherein the focusing apparatus comprises at least two magnetic quadrupoles.

13. The ion implantation system of claim 8, further comprising a power supply operably coupled to the focusing apparatus and configured to control the trajectory of the ions within the passageway of the stripper tube via one of a current and voltage supplied to the focusing apparatus.

14. A charge stripping system for an ion implantation system, the charge stripping system comprising:
a charge stripper positioned between a first RF linear accelerator and a second RF linear accelerator along a beam path of ions of an ion beam, wherein the charge stripper comprises a stripper tube having a passageway therethrough and a focusing apparatus surrounding the stripper tube;
a gas source configured to supply stripper gas to the passageway of the stripper tube;
a power supply operably coupled to the focusing apparatus; and
a controller configured to control a trajectory of the ions within the passageway by controlling a current or a voltage from the power supply to the focusing apparatus.

15. The charge stripping system of claim 14, wherein the stripper tube consists of an electrically insulative material, and wherein the focusing apparatus comprises at least two electrostatic quadrupoles.

16. The charge stripping system of claim 14, wherein the stripper tube comprises an electrically conductive material, and wherein the focusing apparatus comprises at least two magnetic quadrupoles.

17. A beam control apparatus for focusing an ion beam passing through a charge stripper, the beam control apparatus comprising:
a charge stripper housing;
a stripper tube positioned within the charge stripper housing, the stripper tube comprising a passageway configured to pass the ion beam through a charge stripping medium, wherein the ion beam comprises ions having an initial trajectory; and
a focusing apparatus positioned within the charge stripper housing and configured to control a trajectory of the ions within the passageway of the stripper tube.

18. The beam control apparatus of claim 17, wherein the focusing apparatus comprises at least two electrostatic quadrupoles.

19. The beam control apparatus of claim 17, wherein the focusing apparatus comprises at least two magnetic quadrupoles.

20. The beam control apparatus of claim 17, wherein the focusing apparatus comprises one or more of a solenoid and an Einzel lens.
